(19) United States
(12) Patent Application Publication
(10) Pub. No.: US 2026/0157008 A1
(43) Pub. Date: Jun. 4, 2026

(54) TRANSPARENT DISPLAY

(71) Applicant: AUO Corporation, Hsinchu City (TW)

(72) Inventors: Ming-Lung CHEN, Hsinchu City (TW); Kun-Cheng TIEN, Hsinchu City (TW)

(21) Appl. No.: 19/383,983

(22) Filed: Nov. 10, 2025

(30) Foreign Application Priority Data
Nov. 29, 2024 (TW) 113146448

(51) Int. Cl. H10H 29/855

(52) U.S. Cl. CPC H10H 29/8552

(57) ABSTRACT

A transparent display provided with a display panel having pixel structures, and driver chips electrically connected to the display panel and disposed along a first direction. The pixel structure includes a high brightness light-emitting element and first to fourth black matrixes. The first and second black matrixes are respectively extended along a second direction and opposite to each other. The first direction is vertical to the second direction. The third and fourth black matrixes are located between the first and second black matrixes, and respectively extended along the first direction and opposite to each other. The first to fourth black matrixes surround the high brightness light-emitting element. First to fourth distances are respectively located between the high brightness light-emitting element and the first to fourth black matrixes. The fourth distance is a minimum distance among the first to fourth distances and not less than 40 um.

### CROSS-REFERENCE TO RELATED APPLICATION

This application claims priority to Taiwan Application Serial Number 113146448, filed Nov. 29, 2024, which is herein incorporated by reference in its entirety.

### BACKGROUND

### Field of Invention

The present invention relates to a transparent display. More particularly, the present invention relates to a transparent display with low back side light leakage.

### Description of Related Art

With the development of technology and economy, the functions of various electronic products are increasing to meet the needs of users for electronic products. A display is a common electronic product, which is used to play image data for users to view. Among them, a transparent display is popular with users because it allows users to see the displayed objects or scenes behind it. Generally speaking, a transparent display is applied to large-scale commercial displays, shop windows, or display windows of merchandise showcases to achieve the purpose of simultaneously displaying advertising images and merchandise.

However, current transparent displays have large light leakage on the back side, which affects the user's experience of viewing the transparent display.

### SUMMARY

An objective of the present invention is to provide a transparent display, which can improve the back side light leakage of the transparent display and enhance the user's experience of viewing the transparent display.

According to an embodiment of the present invention, a transparent display includes: a first transparent sub-display. The first transparent sub-display includes: a first display panel and a plurality of first driver chips. The first display panel includes a plurality of first pixel structures. The first driver chips are electrically connected to the first display panel, and are disposed along a first direction. Each of the first pixel structures includes: a first high brightness light-emitting element, a first black matrix, a second black matrix, a third black matrix, and a fourth black matrix. The first black matrix is extended along a second direction. The second direction is vertical to the first direction. The second black matrix is extended along the second direction and opposite to the first black matrix. The third black matrix is disposed between the first black matrix and the second black matrix, and is extended along the first direction. The fourth black matrix is disposed between the first black matrix and the second black matrix, and is extended along the first direction. The fourth black matrix is opposite to the third black matrix. The first black matrix, the second black matrix, the third black matrix, and the fourth black matrix surround the first high brightness light-emitting element. A first distance is located between the first high brightness light-emitting element and the first black matrix. A second distance is located between the first high brightness light-emitting element and the second black matrix. A third distance is located between the first high brightness light-emitting element and the third black matrix. A fourth distance is located between the first high brightness light-emitting element and the fourth black matrix. The fourth distance is a minimum distance among the first distance, the second distance, the third distance, and the fourth distance, and is greater than or equal to 40 micrometers (um).

In some embodiments, the transparent display further includes a second transparent sub-display. The second transparent sub-display is spliced to the first transparent sub-display. The second transparent sub-display includes: a second display panel and a plurality of second driver chips. The second display panel includes a plurality of second pixel structures. The second driver chips are electrically connected to the second display panel, wherein the second driver chips are disposed along the first direction. Each of the second pixel structures includes: a second high brightness light-emitting element, a fifth black matrix, a sixth black matrix, a seventh black matrix, and an eighth black matrix. The fifth black matrix is extended along the second direction. The sixth black matrix is extended along the second direction and opposite to the fifth black matrix. The seventh black matrix is disposed between the fifth black matrix and the sixth black matrix, and is extended along the first direction. The eighth black matrix is disposed between the fifth black matrix and the sixth black matrix, and is extended along the first direction, wherein the eighth black matrix is opposite to the seventh black matrix. The fifth black matrix, the sixth black matrix, the seventh black matrix, and the eighth black matrix surround the second high brightness light-emitting element. A fifth distance is located between the second high brightness light-emitting element and the fifth black matrix. A sixth distance is located between the second high brightness light-emitting element and the sixth black matrix. A seventh distance is located between the second high brightness light-emitting element and the seventh black matrix. An eighth distance is located between the second high brightness light-emitting element and the eighth black matrix. The eighth distance is a minimum distance among the fifth distance, the sixth distance, the seventh distance, and the eighth distance, and is greater than or equal to 40 um.

In some embodiments, the first pixel structure is spliced with the second pixel structure. The first pixel structure includes a plurality of first light-emitting elements, and the first high brightness light-emitting element is one of the first light-emitting elements. The second pixel structure includes a plurality of second light-emitting elements, and the second high brightness light-emitting element is one of the second light-emitting elements. The first light-emitting elements and the second light-emitting elements are arranged along the first direction.

In some embodiments, the first high brightness light-emitting element and the second high brightness light-emitting element are green light-emitting diode elements.

In some embodiments, the first pixel structure is spliced with the second pixel structure, and a splicing seam is defined. The first pixel structure includes a plurality of first light-emitting elements, and the first high brightness light-emitting element is one of the first light-emitting elements. The second pixel structure includes a plurality of second light-emitting elements, and the second high brightness light-emitting element is one of the second light-emitting elements. The first light-emitting elements and the second light-emitting elements are arranged along the second direction. The first light-emitting elements include a plurality of first splicing light-emitting elements at the splicing seam. The second light-emitting elements include a plurality of second splicing light-emitting elements at the splicing seam. The color of the first splicing light-emitting elements is different from the color of the second splicing light-emitting elements.

In some embodiments, the minimum of the first distance, the second distance, the third distance, and the fourth distance is located in the second direction, or the minimum of the fifth distance, the sixth distance, the seventh distance, and the eighth distance is located in the second direction.

In some embodiments, the third distance is greater than or equal to 40 um.

In some embodiments, the sum of the first distance and the second distance is greater than the sum of the third distance and the fourth distance.

In some embodiments, the first distance and the second distance are located in the first direction. The minimum of the third distance and the fourth distance is located in the second direction. The first high brightness light-emitting element is located at a main placement position or a repair position.

In some embodiments, the first transparent sub-display further includes a plurality of driving lines. The driving lines are electrically connected to one of the first driver chips. The driving lines have a line extension direction, and the line extension direction is vertical to the first direction. The first high brightness light-emitting element is disposed in a rectangular bonding region, and the longest side of the rectangular bonding region is parallel to the first direction.

According to an embodiment of the present invention, a transparent display includes: a first transparent sub-display and a second transparent sub-display. The first transparent sub-display has a first edge along a first direction. The second transparent sub-display has a second edge along the first direction. The second edge is spliced with the first edge in a second direction perpendicular to the first direction. A splice seam is defined. The first transparent sub-display includes: a first high brightness light-emitting element positioned at the splice seam; and a first rectangular black matrix surrounding the first high brightness light-emitting element. The second transparent sub-display includes: a second high brightness light-emitting element positioned at the splice seam; and a second rectangular black matrix surrounding the second high brightness light-emitting element. The minimum distance among the distances from the first high brightness light-emitting element to the four sides of the first rectangular black matrix is located in the second direction. The minimum distance among the distances from the second high brightness light-emitting element to the four sides of the second rectangular black matrix is located in the second direction.

In some embodiments, the minimum distance among the distances from the first high brightness light-emitting element to the four sides of the first rectangular black matrix is greater than or equal to 40 um. The minimum distance among the distances from the second high brightness light-emitting element to the four sides of the second rectangular black matrix is greater than or equal to 40 um.

In some embodiments, the first high brightness light-emitting element and the second high brightness light-emitting element face each other across the splicing seam in the second direction. The color of the first high brightness light-emitting element is different from the color of the second high brightness light-emitting element.

In some embodiments, the long sides of the first rectangular black matrix are located in the first direction, and the short sides of the first rectangular black matrix are located in the second direction. The long sides of the second rectangular black matrix are located in the first direction, and the short sides of the second rectangular black matrix are located in the second direction.

In some embodiments, the long side of the first rectangular black matrix near the splicing seam shields a scan line of the first transparent sub-display, and the long side of the second rectangular black matrix near the splicing seam shields a scan line of the second transparent sub-display.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic diagram illustrating a simple structure of a transparent display according to an embodiment of the present invention;

FIG. 2 is a schematic diagram illustrating a pixel structure of a first display panel according to an embodiment of the present invention;

FIG. 3 is a schematic diagram illustrating a main placement position and a standby repair position of a high brightness light-emitting element according to an embodiment of the present invention;

FIG. 4 is a schematic diagram illustrating a wiring line width according to an embodiment of the present invention;

FIG. 5 is a schematic diagram illustrating the splicing of a first display panel of a first transparent sub-display and a second display panel of a second transparent sub-display according to another embodiment of the present invention;

FIG. 6 is a schematic diagram illustrating the splicing of a first display panel of a first transparent sub-display and a second display panel of a second transparent sub-display according to yet another embodiment of the present invention; and

FIG. 7 is a schematic diagram illustrating two pixel structures spliced to each other according to still another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The embodiments are described in detail below with reference to the accompanying drawings, but the provided embodiments are not intended to limit the scope covered by the present invention. The description of the structural operation is not intended to limit the sequence of its execution. Any device produced by the re-combination of elements that has equivalent efficacy is covered by the scope of the present invention. Furthermore, the drawings are for illustrative purposes only and are not drawn to scale.

The terms “first”, “second”, etc., used herein do not specifically refer to order or rank, but are only used to distinguish between components or operations described with the same technical terms.

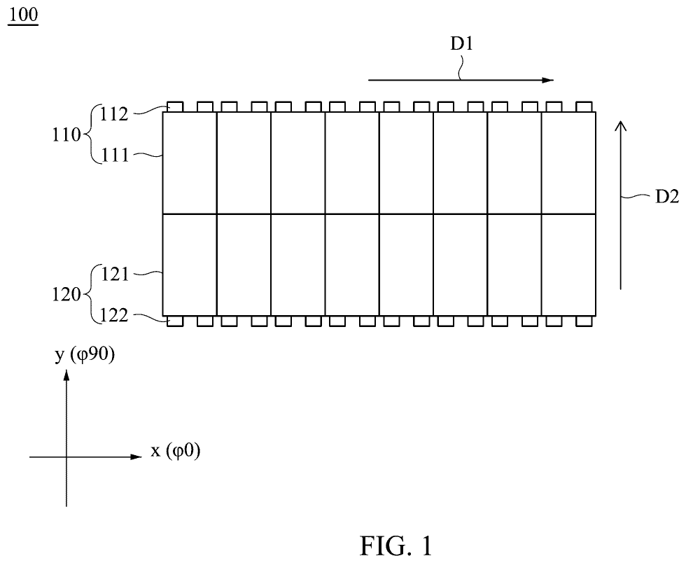

Please refer to FIG. 1, which is a schematic diagram illustrating a simple structure of a transparent display 100 according to an embodiment of the present invention. The transparent display 100 includes a plurality of first transparent sub-displays 110 and a plurality of second transparent sub-displays 120. The first transparent sub-displays 110 and the second transparent sub-displays 120 are spliced to each other to form a larger-sized transparent display 100. The first transparent sub-displays 110 are spliced to each other along a first direction D1 (i.e., the x-axis direction). The first transparent sub-display 110 has a first edge (lower edge in FIG. 1) along the first direction D1. The second transparent sub-displays 120 are spliced to each other along the first direction D1. The second transparent sub-display 120 has a second edge (upper edge in FIG. 1) along the first direction D1. The first edge and the second edged are spliced to each other along the second direction D2 (i.e., the y-axis direction). Namely, the first transparent sub-displays 110 and the corresponding second transparent sub-displays 120 are spliced to each other along a second direction D2, thereby forming the transparent display 100. However, the embodiments of the present invention are not limited thereto. In this embodiment, the transparent display 100 includes two rows of transparent sub-displays spliced to each other. However, in other embodiments of the present invention, the transparent display 100 may include only one row of transparent sub-displays spliced to each other, or more rows of transparent sub-displays.

The first transparent sub-display 110 includes a first display panel 111 and a plurality of first driver chips 112. The first driver chips 112 are disposed along the first direction D1 to be electrically connected to the first display panel 111 to drive the corresponding first display panel 111. In this embodiment, the first driver chips 112 are Chip on Film (COF), but the embodiments of the present invention are not limited thereto. Similarly, the second transparent sub-display 120 includes a second display panel 121 and a plurality of second driver chips 122. The second driver chips 122 are disposed along the first direction D1 to be electrically connected to the second display panel 121 to drive the corresponding second display panel 121. In this embodiment, the second driver chips 122 are also Chip on Film, but the embodiments of the present invention are not limited thereto.

For convenience of representation, the x-axis direction is represented by φ=0, and the y-axis direction is represented by φ=90. For example, the angle between the first direction D1 and the x-axis is 0 degree. Also, the angle between the second direction D2 and the x-axis is 90 degrees.

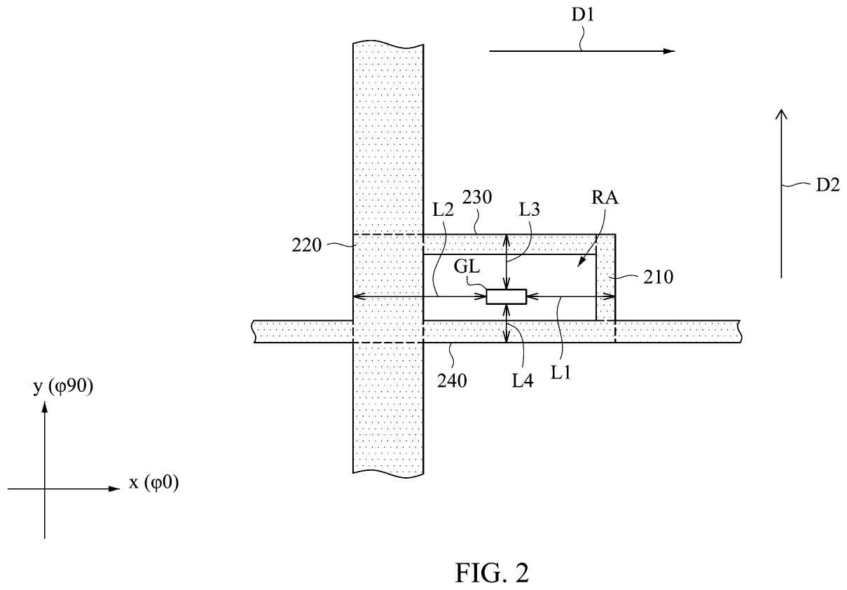

Please refer to FIG. 2, which is a schematic diagram illustrating the pixel structure of the first display panel 111 according to an embodiment of the present invention. The first display panel 111 includes a plurality of pixel structures to display image data using these pixel structures. The pixel structure includes a black matrix and a plurality of light-emitting elements. In this embodiment, as shown in FIG. 2, only a first black matrix 210, a second black matrix 220, a third black matrix 230, a fourth black matrix 240, and a high brightness light-emitting element GL among the light-emitting elements are shown. In the embodiments of the present invention, the light-emitting elements are red, blue, and green light-emitting diodes, and the high brightness light-emitting element GL is a green light-emitting diode.

The light-emitting element of this embodiment, such as the high brightness light-emitting element GL, is disposed in a bonding region RA. The first black matrix 210, the second black matrix 220, the third black matrix 230, and the fourth black matrix 240 surround the bonding region RA to shield the wirings on the first display panel 111 and provide a color separation effect.

The first black matrix 210 and the second black matrix 220 are located on the left and right sides of the bonding region RA and are opposite to each other. The first black matrix 210 and the second black matrix 220 are extended along the second direction D2. In this embodiment, the second black matrix 220 corresponds to shielding the data lines of the first display panel 111. The third black matrix 230 and the fourth black matrix 240 are located on the upper and lower sides of the bonding region RA and are opposite to each other. The third black matrix 230 and the fourth black matrix 240 are located between the first black matrix 210 and the second black matrix 220, and are extended along the first direction D1. In this embodiment, the second black matrix 220 corresponds to shielding the scan lines of the first display panel 111.

A first distance L1 is located between the high brightness light-emitting element GL and the first black matrix 210. A second distance L2 is located between the high brightness light-emitting element GL and the second black matrix 220. A third distance L3 is located between the high brightness light-emitting element GL and the third black matrix 230. A fourth distance L4 is located between the high brightness light-emitting element GL and the fourth black matrix 240. In this embodiment, in order to reduce back side light leakage, the first distance L1, the second distance L2, the third distance L3, and the fourth distance L4 are designed as follows: the sum of the first distance L1 and the second distance L2 is greater than the sum of the third distance L3 and the fourth distance L4. The values of the third distance L3 and the fourth distance L4 are greater than or equal to 40 micrometers (um) and less than or equal to 200 um. The minimum of the first distance L1, the second distance L2, the third distance L3, and the fourth distance L4 is located at φ=90, i.e., extended along the second direction D2.

Through the above design, the amount of back side light leakage of the transparent display 100 according to the embodiments of the present invention can be reduced, for example, by about 4 times.

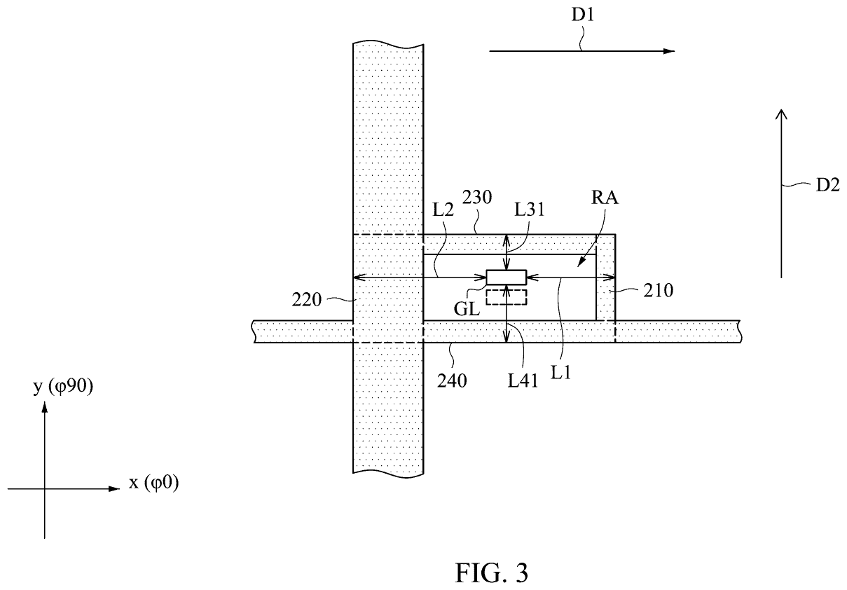

Please refer to FIG. 3. In some embodiments, considering that the high brightness light-emitting element GL may not be able to be disposed at the expected main placement position (indicated by the dashed box), and can only be moved upward to be disposed at the standby repair position. In this case, a third distance L31 is located between the high brightness light-emitting element GL and the third black matrix 230. A fourth distance L41 is located between the high brightness light-emitting element GL and the fourth black matrix 240. Considering the position change of the high brightness light-emitting element GL, the above distances are designed such that the minimum of the third distance L3/L31 and the fourth distance L4/L41 is located at φ=90, i.e., extended along the second direction D2. In this way, the back side light leakage phenomenon of the transparent display 100 can be improved.

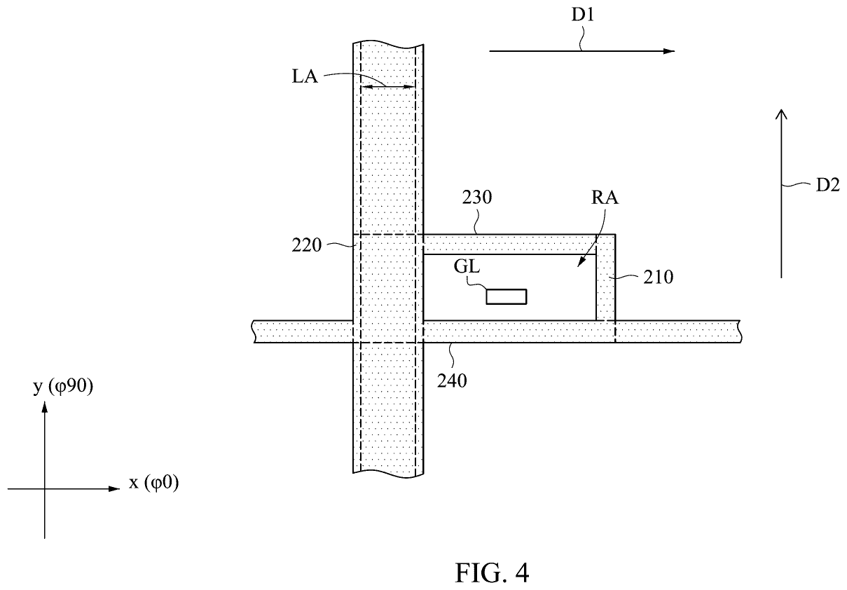

Please refer to FIG. 4. In some embodiments, considering that the wirings on the transparent display 100 will affect light diffraction, the wirings on the transparent display 100, such as the data lines, are routed as concentrated as possible, for example, having a smaller wiring line width LA. In addition, in this embodiment, the extension direction of the line with the largest wiring line width (which is the data line in this embodiment) is vertical to the first direction D1, which is the direction in which the COFs are arranged.

Furthermore, considering that the bonding region RA is rectangular, the longest side of the rectangular bonding region RA is designed to be parallel to the first direction D1 to further improve the back side light leakage phenomenon of the transparent display 100.

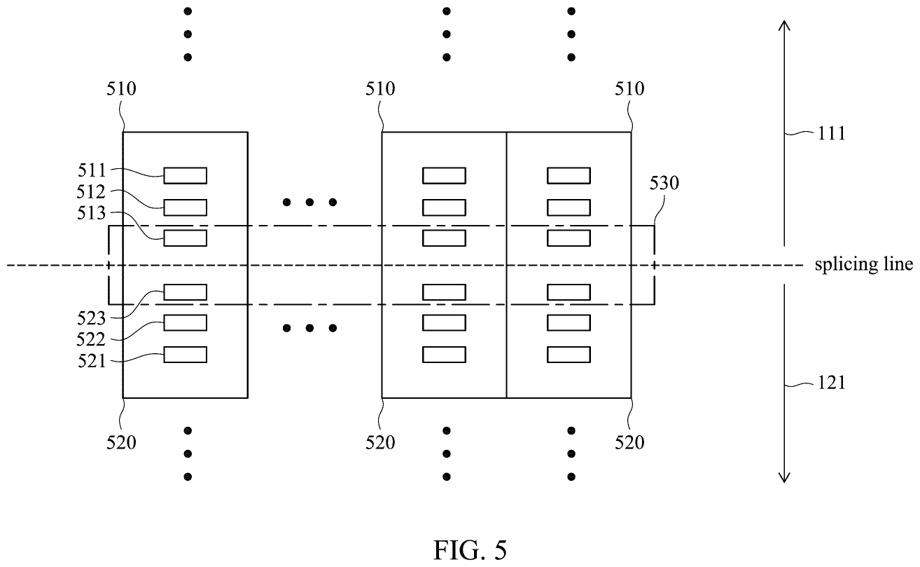

Please refer to FIG. 5, which is a schematic diagram illustrating the splicing of a first display panel 111 of a first transparent sub-display 110 and a second display panel 121 of a second transparent sub-display 120 according to another embodiment of the present invention. As shown in FIG. 5, the first display panel 111 includes a plurality of pixel structures 510. Each of the pixel structures 510 includes a plurality of first light-emitting elements 511, 512, and 513. Similarly, the second display panel 121 includes a plurality of pixel structures 520. Each of the pixel structures 520 includes a plurality of second light-emitting elements 521, 522, and 523. In this embodiment, the first light-emitting elements 511, 512, and 513 include red light-emitting diodes, blue light-emitting diodes, and green light-emitting diodes. The second light-emitting elements 521, 522, and 523 also include red light-emitting diodes, blue light-emitting diodes, and green light-emitting diodes, but the embodiments of the present invention are not limited thereto.

The pixel structures 510 of the first display panel 111 and the pixel structures 520 of the second display panel 121 are spliced at a splicing line, and a splicing seam 530 is defined. In this embodiment, the splicing seam 530 includes adjacent first light-emitting element 513 in the pixel structure 510 and second light-emitting element 523 in the pixel structure 520. In other words, the first light-emitting element 513 is the light-emitting element in the pixel structure 510 that is closest to the pixel structure 520. The second light-emitting element 523 is the light-emitting element in the pixel structure 520 that is closest to the pixel structure 510. In this embodiment, if the first light-emitting element 513 and the second light-emitting element 523 are light-emitting elements of the same color, for example, blue light-emitting elements, a noticeable blue line will appear at the splicing seam 530. Therefore, this embodiment designs the first light-emitting element 513 and the second light-emitting element 523 to be light-emitting elements of different colors to avoid the appearance of a noticeable color stripe at the splicing seam 530.

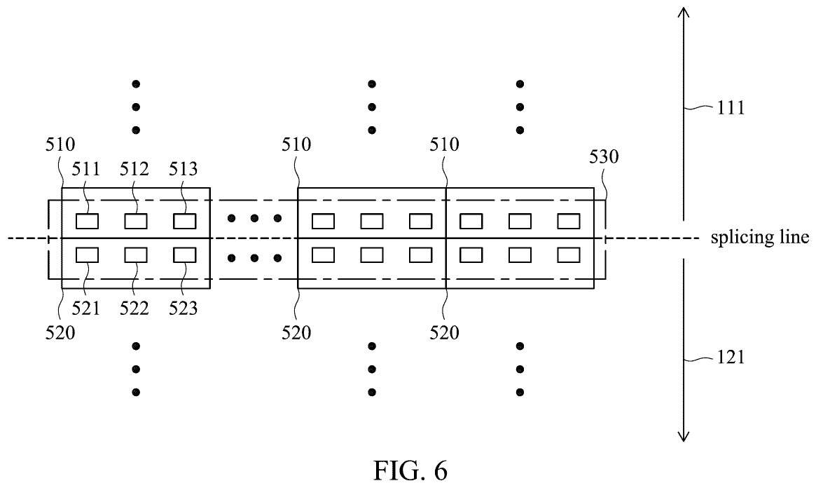

Please refer to FIG. 6, which is a schematic diagram illustrating the splicing of a first display panel 111 of a first transparent sub-display and a second display panel 121 of a second transparent sub-display according to yet another embodiment of the present invention. The embodiment of FIG. 6 is similar to the embodiment of FIG. 5, except that the embodiment of FIG. 6 horizontally disposes the first light-emitting elements 511, 512, and 513 and the second light-emitting elements 521, 522, and 523. In this way, the splicing seam 530 includes the adjacent first light-emitting element 511 and second light-emitting element 521 in the pixel structure 510 and the pixel structure 520, the adjacent first light-emitting element 512 and second light-emitting element 522, and the adjacent first light-emitting element 513 and second light-emitting element 523. Since the light-emitting elements of this embodiment are arranged horizontally, and the colors of the light-emitting elements are different from each other (for example, red, blue, and green), the appearance of a noticeable color stripe at the splicing seam 530 can also be avoided.

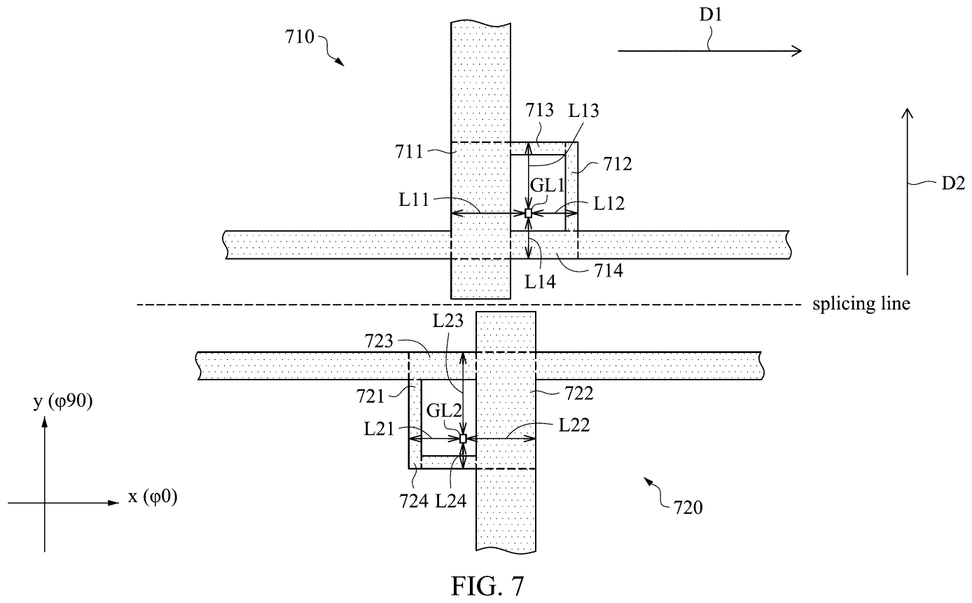

Please refer to FIG. 7, which is a schematic diagram illustrating two pixel structures 710 and 720 spliced to each other according to still another embodiment of the present invention. The pixel structure 710 is located in the first display panel 111, and the pixel structure 720 is located in the second display panel 121. The pixel structure 710 includes a black matrix and a plurality of light-emitting elements. In this embodiment, as shown in FIG. 7, the pixel structure 710 includes a first black matrix 711, a second black matrix 712, a third black matrix 713, a fourth black matrix 714 (the first black matrix 711, the second black matrix 712, the third black matrix 713, and the fourth black matrix 714 form a first rectangular black matrix), and a first high brightness light-emitting element GL1. Similarly, the pixel structure 720 also includes a black matrix and a plurality of light-emitting elements. As shown in FIG. 7, the pixel structure 720 includes a fifth black matrix 721, a sixth black matrix 722, a seventh black matrix 723, an eighth black matrix 724 (the fifth black matrix 721, the sixth black matrix 722, the seventh black matrix 723, and the eighth black matrix 724 form a second rectangular black matrix), and a second high brightness light-emitting element GL2. In this embodiment, the light-emitting elements in the pixel structures 710 and 720, such as red, blue, and green light-emitting diodes, are extended at φ=90, i.e., arranged along the second direction D2.

The first black matrix 711 and the second black matrix 712 are located on the left and right sides of the first high brightness light-emitting element GL1 and are opposite to each other. The first black matrix 711 and the second black matrix 712 are extended along the second direction D2. In this embodiment, the first black matrix 711 corresponds to shielding the data lines of the first display panel 111. The third black matrix 713 and the fourth black matrix 714 are located on the upper and lower sides of the first high brightness light-emitting element GL1 and are opposite to each other. The third black matrix 713 and the fourth black matrix 714 are extended along the first direction D1. In this embodiment, the fourth black matrix 714 corresponds to shielding the scan lines of the first display panel 111.

The fifth black matrix 721 and the sixth black matrix 722 are located on the left and right sides of the second high brightness light-emitting element GL2 and are opposite to each other. The fifth black matrix 721 and the sixth black matrix 722 are extended along the second direction D2. In this embodiment, the sixth black matrix 722 corresponds to shielding the data lines of the second display panel 121. The seventh black matrix 723 and the eighth black matrix 724 are located on the upper and lower sides of the second high brightness light-emitting element GL2 and are opposite to each other. The seventh black matrix 723 and the eighth black matrix 724 are extended along the first direction D1. In this embodiment, the seventh black matrix 723 corresponds to shielding the scan lines of the second display panel 121.

A first distance L11 is located between the first high brightness light-emitting element GL1 and the first black matrix 711. A second distance L12 is located between the first high brightness light-emitting element GL1 and the second black matrix 712. A third distance L13 is located between the first high brightness light-emitting element GL1 and the third black matrix 713. A fourth distance L14 is located between the first high brightness light-emitting element GL1 and the fourth black matrix 714. A fifth distance L21 is located between the second high brightness light-emitting element GL2 and the fifth black matrix 721. A sixth distance L22 is located between the second high brightness light-emitting element GL2 and the sixth black matrix 722. A seventh distance L23 is located between the second high brightness light-emitting element GL2 and the seventh black matrix 723. An eighth distance L24 is located between the second high brightness light-emitting element GL2 and the eighth black matrix 724. In this embodiment, in order to reduce back side light leakage, the first distance L11, the second distance L12, the third distance L13, the fourth distance L14, the fifth distance L21, the sixth distance L22, the seventh distance L23, and the eighth distance L24 are designed as follows: the minimum of the first distance L11, the second distance L12, the third distance L13, and the fourth distance L14 is located at φ=90, i.e., extended along the second direction D2. The minimum of the fifth distance L21, the sixth distance L22, the seventh distance L23, and the eighth distance L24 is located at φ=90, i.e., extended along the second direction D2. In other words, in the two pixel structures 710 and 720, the minimum distance appears below the pixel structures 710 and 720. In this way, the back side light leakage phenomenon of the transparent display 100 can be improved.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A transparent display, comprising:
a first transparent sub-display, comprising:
a first display panel, comprising a plurality of first pixel structures; and
a plurality of first driver chips, electrically connected to the first display panel, wherein the first driver chips are disposed along a first direction;
wherein each of the first pixel structures comprises:
a first high brightness light-emitting element;
a first black matrix, extended along a second direction, the second direction being vertical to the first direction;
a second black matrix, extended along the second direction, and opposite to the first black matrix;
a third black matrix, disposed between the first black matrix and the second black matrix, and extended along the first direction; and
a fourth black matrix, disposed between the first black matrix and the second black matrix, and extended along the first direction, wherein the fourth black matrix is opposite to the third black matrix;
wherein the first black matrix, the second black matrix, the third black matrix, and the fourth black matrix surround the first high brightness light-emitting element; a first distance is located between the first high brightness light-emitting element and the first black matrix; a second distance is located between the first high brightness light-emitting element and the second black matrix; a third distance is located between the first high brightness light-emitting element and the third black matrix; and a fourth distance is located between the first high brightness light-emitting element and the fourth black matrix, wherein the fourth distance is a minimum distance among the first distance, the second distance, the third distance, and the fourth distance, and is greater than or equal to 40 um.

2. The transparent display of claim 1, further comprising:
a second transparent sub-display, spliced to the first transparent sub-display, wherein the second transparent sub-display comprises:
a second display panel, comprising a plurality of second pixel structures;
a plurality of second driver chips, electrically connected to the second display panel, wherein the second driver chips are disposed along the first direction;
wherein each of the second pixel structures comprises:
a second high brightness light-emitting element;
a fifth black matrix, extended along the second direction;
a sixth black matrix, extended along the second direction, and opposite to the fifth black matrix;
a seventh black matrix, disposed between the fifth black matrix and the sixth black matrix, and extended along the first direction; and
an eighth black matrix, disposed between the fifth black matrix and the sixth black matrix, and extended along the first direction, wherein the eighth black matrix is opposite to the seventh black matrix;
wherein the fifth black matrix, the sixth black matrix, the seventh black matrix, and the eighth black matrix surround the second high brightness light-emitting element; a fifth distance is located between the second high brightness light-emitting element and the fifth black matrix; a sixth distance is located between the second high brightness light-emitting element and the sixth black matrix; a seventh distance is located between the second high brightness light-emitting element and the seventh black matrix; and an eighth distance is located between the second high brightness light-emitting element and the eighth black matrix, wherein the eighth distance is a minimum distance among the fifth distance, the sixth distance, the seventh distance, and the eighth distance, and is greater than or equal to 40 um.

3. The transparent display of claim 2, wherein the first pixel structures are spliced with the second pixel structures; the first pixel structures comprise a plurality of first light-emitting elements; the first high brightness light-emitting element is one of the first light-emitting elements; the second pixel structures comprise a plurality of second light-emitting elements; the second high brightness light-emitting element is one of the second light-emitting elements; the first light-emitting elements are arranged along the first direction; and the second light-emitting elements are arranged along the first direction.

4. The transparent display of claim 2, wherein the first high brightness light-emitting element and the second high brightness light-emitting element are green light-emitting diode elements.

5. The transparent display of claim 2, wherein the first pixel structures are spliced with the second pixel structures, and a splicing seam is defined; the first pixel structures comprise a plurality of first light-emitting elements; the first high brightness light-emitting element is one of the first light-emitting elements; the second pixel structures comprise a plurality of second light-emitting elements; the second high brightness light-emitting element is one of the second light-emitting elements; the first light-emitting elements are arranged along the second direction; the second light-emitting elements are arranged along the second direction; the first light-emitting elements have a plurality of first splicing light-emitting elements at the splicing seam; the second light-emitting elements have a plurality of second splicing light-emitting elements at the splicing seam; and the color of the first splicing light-emitting elements is different from the color of the second splicing light-emitting elements.

6. The transparent display of claim 5, wherein the minimum of the first distance, the second distance, the third distance, and the fourth distance is located in the second direction, or the minimum of the fifth distance, the sixth distance, the seventh distance, and the eighth distance is located in the second direction.

7. The transparent display of claim 1, wherein the third distance is greater than or equal to 40 um.

8. The transparent display of claim 1, wherein the sum of the first distance and the second distance is greater than the sum of the third distance and the fourth distance.

9. The transparent display of claim 1, wherein the first distance and the second distance are located in the first direction; the minimum of the third distance and the fourth distance is located in the second direction; and the first high brightness light-emitting element is located at a main placement position or a repair position.

10. The transparent display of claim 1, wherein the first transparent sub-display further comprises a plurality of driving lines; the driving lines are electrically connected to one of the first driver chips; the driving lines have a line extension direction; the line extension direction is vertical to the first direction; the first high brightness light-emitting element is disposed in a rectangular bonding region; and the longest side of the rectangular bonding region is parallel to the first direction.

11. A transparent display, comprising:
a first transparent sub-display, having a first edge along a first direction; and
a second transparent sub-display, having a second edge along the first direction, the second edge being spliced with the first edge in a second direction perpendicular to the first direction, defining a splice seam,
wherein the first transparent sub-display comprises:
a first high brightness light-emitting element, positioned at the splice seam; and
a first rectangular black matrix, surrounding the first high brightness light-emitting element,
wherein the second transparent sub-display comprises:
a second high brightness light-emitting element, positioned at the splice seam; and
a second rectangular black matrix, surrounding the second high brightness light-emitting element,
wherein the minimum distance among the distances from the first high brightness light-emitting element to the four sides of the first rectangular black matrix is located in the second direction, and the minimum distance among the distances from the second high brightness light-emitting element to the four sides of the second rectangular black matrix is located in the second direction.

12. The transparent display of claim 11, wherein the minimum distance among the distances from the first high brightness light-emitting element to the four sides of the first rectangular black matrix is greater than or equal to 40 um, and the minimum distance among the distances from the second high brightness light-emitting element to the four sides of the second rectangular black matrix is greater than or equal to 40 um.

13. The transparent display of claim 11, wherein the first high brightness light-emitting element and the second high brightness light-emitting element face each other across the splicing seam in the second direction; and the color of the first high brightness light-emitting element is different from the color of the second high brightness light-emitting element.

14. The transparent display of claim 11, wherein the long sides of the first rectangular black matrix are located in the first direction, and the short sides of the first rectangular black matrix are located in the second direction; and the long sides of the second rectangular black matrix are located in the first direction, and the short sides of the second rectangular black matrix are located in the second direction.

15. The transparent display of claim 14, wherein the long side of the first rectangular black matrix near the splicing seam shields a scan line of the first transparent sub-display, and the long side of the second rectangular black matrix near the splicing seam shields a scan line of the second transparent sub-display.
